(19) United States
(12) Patent Application Publication
(10) Pub. No.: US 2014/0373906 A1
(43) Pub. Date: Dec. 25, 2014

(54) ANTI-REFLECTION COATINGS FOR MULTIJUNCTION SOLAR CELLS

(71) Applicant: SOLAR JUNCTION CORPORATION, San Jose, CA (US)

(72) Inventors: Ferran Suarez, San Jose, CA (US); Robert Bergner, Dublin, CA (US); Daniel Derkacs, Albuquerque, NM (US)

(21) Appl. No.: 14/311,642

(22) Filed: Jun. 23, 2014

Related U.S. Application Data
(60) Provisional application No. 61/839,031, filed on Jun. 25, 2013.
(60) Provisional application No. 61/857,609, filed on Jul. 23, 2013.

(51) Int. Cl. H01L 31/0216; H01L 31/0725

(52) U.S. Cl. CPC H01L 31/02168; H01L 31/0725
USPC 136/255; 136/256

(57) ABSTRACT

Anti-reflection coatings (ARC) on solar cells for terrestrial and space use are disclosed, particularly for multi junction solar cells, to maximize transmission of incident light into the active region of the semiconductor solar cell over a wide spectral band.

This application claims benefit under 35 U.S.C. §119(e) of U.S. Provisional Application No. 61/839,031 filed on Jun. 25, 2013, and U.S. Provisional Application No. 61/857,609 filed on Jul. 23, 2013, each of which is incorporated by reference in its entirety.

### FIELD

This invention relates to anti-reflection coatings (ARC) on solar cells for terrestrial and space use, particularly for multi junction solar cells, to maximize transmission of incident light into the active region of the semiconductor solar cell over a wide spectral band.

### BACKGROUND

Conventional light detection devices have features that reduce the efficiency of optical (e.g., solar) to electrical energy conversion. For example, high efficiency solar cells are typically manufactured using photoactive semiconductor absorbers of high refractive index (refractive index hereby denoted by “n” as known in the field), leading to a large difference between the incident media refractive index (typically air at n=1) and that of the semiconductor (n≈3.5). The difference in refractive index results in high surface reflection (typically 30% to 40%) over a wide spectral band, which reduces the amount of incident light that transmits into the photoactive regions of the solar cell. To mitigate this loss, single or multiple layer ARCs are used to improve the transmission of light into the device and subsequently increase the power conversion efficiency of the solar cell.

Conventional multi junction solar cells have been widely used for terrestrial and space applications. Multijunction solar cells comprise multiple diodes (junctions or subcells) in series connection, realized by growing thin layered regions of epitaxy on semiconductor substrates. Subcells of different materials are grown on a substrate of appropriate atomic lattice constant; each having progressively higher bandgap energy than the cell below, allowing each subcell to absorb a specific spectral band of the solar spectrum. Because the subcells are connected in series by tunnel junctions, the output current of the multijunction cell should be divided equally between each subcell in order to maximize power conversion efficiency. Power conversion efficiency is improved over that of a single junction solar cell via the additional voltage contributed by each subcell, and furthermore by the ability to add lower bandgap energy subcells that capture a greater fraction of the infrared (IR) portion of the solar spectrum that is not typically captured by single junction solar cells. Thus, the more subcells a multijunction solar cell has, the higher the efficiency can be. However, when more subcells are used to capture a greater fraction of the solar spectrum, an effective ARC has to minimize surface reflections over a wider wavelength range compared to conventional single junction solar cells.

In prior art multi junction solar cell manufacturing, the semiconductor area of the cell facing the sun is coated with an ARC to reduce the reflection of sunlight, thereby increasing overall cell efficiency. ARCs typically consist of a stack of thin film dielectric materials of varying thicknesses, chemical compositions, and refractive indices. The refractive index of each layer is predetermined by the material selection and the thickness of each layer is accurately calculated so as to minimize the reflection of sunlight over the desired wavelength range. FIG. 1 shows a prior art multijunction solar cell with three subcells, a front surface field, and an ARC design on top of the front surface field to reduce reflectivity.

Given that multijunction solar cells consist of series connected pn-junction semiconductor layers that absorb a different fraction of the solar spectrum, the layer—or subcell—which produces the least photocurrent (herein also described as current or external quantum efficiency) is the current limiting subcell for the entire solar cell. In other words, the overall efficiency of the solar cell is critically dependent on the current-limiting subcell. In order to optimize the overall efficiency of the solar cell, the ARC must be designed to minimize the reflectivity at all wavelengths, but in particular, for the subcells that are more likely to be current limiting as terrestrial spectral conditions change throughout the day and year, or as subcells degrade from radiation damage in extraterrestrial environments.

In prior art multijunction solar cell designs with three subcells, such as the industry standard InGaP/InGaAs/Ge solar cell, the ARC is typically made of two layers comprising an oxide compound such as Al₂O₃ or TiO₂ or other similar material. Aiken, “Antireflection coating design for multi-junction, series interconnected solar cells”. Progress in Photovoltaics: Research and Applications 8(6): 563-570. (2000). For this device, the Ge subcell produces excess photocurrent in comparison to the top InGaP and middle InGaAs subcells due to the relatively low bandgap energy of the Ge subcell. Given the excess current in the Ge subcell, the prior art two-layer ARC designs are aimed at reducing the reflectivity for the InGaP and InGaAs subcells and are therefore sufficient to maximize the photocurrent produced by the top two subcells, and therefore the entire cell, at the expense of higher reflectance over the infrared wavelengths that are absorbed by the bottom Ge subcell. In this manner, for three junction multijunction solar cells, the current literature teaches that a trade-off in reflectivity is made in ARC designs between the bottom and top subcells. That is, an ARC design that best minimizes reflectivity losses over the wavelength range absorbed by the bottom subcell does not simultaneously provide the same low reflectivity values for the top subcell.

In addition to reducing reflection, the ARC must be made from transparent materials in order to prevent the ARC itself from absorbing incident light and subsequently preventing the maximum amount of incident light from reaching the subcells. Because many traditional ARC materials are semiconductors, such as TiO₂, they are likely to absorb UV light. In fact, most desirable dielectric materials with refractive index 2≦n≦3.5 absorb UV light below the wavelength of 400 nm, but absorption typically decreases and approaches zero at longer wavelengths. As such, semiconductors generally follow the trend that as bandgap energy increases, the refractive index decreases.

Designing an ARC for multijunction solar cells takes into account, amongst others, the following parameters captured by Snell's Law: (1) the incident angle of light, (2) the refractive indices of the layers of media the light is traveling through (3) the thicknesses of such materials, and (4) the wavelength of the incident light. The literature also teaches that very low reflectivity is best achieved for narrower ranges of wavelength and incident angle. Unfortunately, a narrow wavelength range design approach is impractical for solar cells. This prompts the need for broadband ARC designs that capture a wide incident angle and wide range of wavelengths. Li, et al., Surface profile optimization of antireflection gratings for solar cells, Optik—Int. J. Light Electron Opt. (2011), doi: 10.1016/j.jleo.2010.10.048.

In addition to the factors explained above, recent developments in the field of multijunction solar cells have shown that dilute nitrides subcells with a bandgap of approximately 1.0 eV are desired for improving the efficiency of multijunction solar cells and can be lattice matched to a GaAs or Ge substrate. Dilute nitride-containing multijunction solar cells can be expanded beyond the three junction solar cell into a four or more junction solar cell, using one or more dilute nitride subcells, U.S. Application Publication No. 2013/118546, which is incorporated by reference in its entirety. For such multijunction solar cells with lattice matched dilute nitride subcells, the dilute nitride subcells can absorb light in the infrared region of the spectrum between 850 nm and 1800 nm. As such, it is critical to reduce the infrared reflection loss in order to increase cell performance and efficiency of the solar cell as a whole.

Further, given that an increase in efficiency is desirable in the extraterrestrial and concentrated photovoltaic fields, emphasis has been placed on increasing the number of subcells in multijunction solar cells, including dilute nitride multijunction solar cells, covering an even wider range of the solar spectrum. When the number of junctions is increased in a multijunction solar cell, the reflectivity for longer wavelengths, i.e. beyond 880 nm, has an even larger effect on overall solar cell efficiency. Accordingly, there is a strong need in the field for ARC designs that capture a greater portion of the electromagnetic spectrum including infrared, visible and ultraviolet light, of multijunction solar cells in order to optimize the solar cell efficiency improvements made by the addition of subcells to the device.

Literature in the art suggests that zero reflectance at a singular wavelength can be achieved by a two-layer coating when an optical thickness of ¼wavelength of material is deposited and the refractive index of the materials obey nₒ×n₂²=n₁²×nₛ; where nₒ is the refractive index of the encapsulant, n₁ is that of the topmost ARC layer, n₂ is that of the bottom ARC layer, and nₛ is that of the solar cell. Moys, The theory of double-layer antireflection coatings, Thin Solid Films, 21, pp. 145-157 (1974), doi: 10.1016/0040-6090(74)90097-2. However, the ability to achieve a perfect zero reflection coating over a broad wavelength range is limited by, 1) the fixed film thickness deposited, 2) the refractive index dispersion as a function of wavelength for real materials, and 3) the inability to deposit transparent oxides having the exact refractive index required that obey the mathematical criteria.

Some current art teaches that a well-performing two-layer design consists of a 50 nm to 60 nm thick TiO₂ coating with a refractive index of 2.5 at 500 nm in combination with an 80 nm to 110 nm thick Al₂O₃ coating with a refractive index of 1.6 at 500 nm.

Other literature teaches that “layers should be deposited so that refractive index increases consecutively from air (nₒ) to first coat (nᵢ) to second coat (n₂) to semiconductor (nₛ).” Nelson, The Physics of Solar Cells p. 262.

Additionally, “¼ wavelength optical thickness” is a critical structural component of ARC designs in current art. A ¼wavelength optical thickness is achieved when the layer thickness=(¼×wavelength/n), where it is noted that the wavelength of light inside a material of index of refraction n, is reduced by a factor of n compared to the wavelength of light in air. As stated previously, two-layer ARCs can achieve zero reflectance at a singular wavelength when an optical thickness of ¼wavelength of material is deposited and the refractive index of the materials obey nₒ×n₂²=n₁²×nₛ. An example state of the art design is shown in Table 1a where the physical layer thickness is compared to the in-air wavelength at which the layer is equivalent to a ¼wavelength optical thickness. Furthermore, the state of the art ARC, for two or more layers, is designed such that the ¼wavelength optical thickness of each layer is equal and is approximately centered upon the in-air wavelength of approximately 550 nm where the solar irradiance peaks. See Aiken, “High performance anti-reflection coatings for broadband multi-junction solar cells” Solar Energy Materials and Solar Cells 64 (2000) 393-404.

TABLE 1a
State of the art

| | Layer 0 | Layer 1 | Layer 2 | Encapsulant |
|---|---|---|---|---|
| Physical Thickness | 33 nm | 56 nm | 88 nm | — |
| Material | InAlP | TiO₂ | SiO₂ | SiO₂ |
| Wavelength | — | 550 nm | 550 nm | — |
| corresponding to | | | | |
| ¼ wavelength | | | | |
| optical thickness | | | | |

However, while the literature recognizes the need for ARC designs to cover a greater portion of the light spectrum for multijunction solar cells that include the infrared, visible, and ultraviolet portions of the spectrum (Aiken, “High performance anti-reflection coatings for broadband multi junction solar cells” Solar Energy Materials and Solar Cells 64 (2000) 393-404), there is still a need to design such ARCs for compatible use with multijunction dilute nitride solar cells and that can withstand the cell manufacturing process.

Finally, cost, along with efficiency, is considered in designing an ARC for multijunction solar cells. Balancing increasing ARC layers for greater cell efficiency by lowering reflectivity with increasing costs is a challenge for commercial designs for broadband ARC: “Improved reflectivity over a band of wavelengths can be achieved with two or more thin films. The greater the number of layers, the greater the range of wavelengths over which the reflectivity can be minimized. Multiple layers are not usually practical for solar cells, given their cost and the sensitivity to angle of incidence.” Nelson, The Physics of Solar Cells, p. 262.

### SUMMARY

The present invention provides a cost-effective, multilayer ARC design for use in lattice matched and lattice mismatched (metamorphic) multijunction solar cells that are nominally current matched, where “nominally” refers to subcell photocurrents matched to within 12% of one another at 25° C. under the AM15D solar spectrum, such that the subcells are more closely current matched at higher operational temperatures of 50° C. to 80° C. and/or under optical elements that have low optical transmission over portions of the solar spectrum, through the layering of multiple, where “multiple” refers to more than two, materials of different refractive indices. The disclosed ARC designs greatly improve photocurrent production in the current limiting subcell by simultaneously reducing reflectivity in the infrared, visible, and ultraviolet wavelength ranges compared to the current ARC designs in the art and by increasing the angular acceptance of incident light absorbed while maintaining low absorption of light in the ARC itself. The current invention also produces these results while undergoing processing techniques, which modify the refractive index of the ARC.

In a first aspect, anti-reflection coatings are provided comprising at least one inverted refractive index pair, wherein the at least one inverted refractive index pair comprises an upper layer comprising a first material characterized by a first refractive index and a first thickness; and a lower layer comprising a second material characterized by a second refractive index and a second thickness, wherein the upper layer overlies the lower layer, and the first refractive index is higher than the second refractive index.

In a second aspect, anti-reflection coatings are provided comprising a first layer comprising a first material characterized by a first refractive index and by a first thickness; an inverted refractive index pair overlying the first layer, wherein the inverted refractive index pair comprises a second layer comprising a material characterized by a second refractive index and by a second thickness; and a third layer comprising a material characterized by a third refractive index and by a third thickness; and a fourth layer comprising a material characterized by a fourth refractive index and a fourth thickness overlying the inverted refractive index pair; wherein the first refractive index is greater than the second refractive index; the third refractive index is greater than the second refractive index; and the fourth refractive index is less than the third refractive index.

In a third aspect, multijunction solar cells are provided comprising an epitaxial region comprising a substrate, an uppermost front surface field region, and a plurality of subcells, wherein each of the plurality of subcells is lattice matched to the substrate; a plurality of cap regions overlying a first portion of the uppermost front surface field region; and an antireflection coating overlying a second portion of the uppermost front surface field region, wherein the antireflection coating comprises three or more dielectric films.

### BRIEF DESCRIPTION OF THE DRAWINGS

Those skilled in the art will understand that the drawings described herein are for illustration purposes only. The drawings are not intended to limit the scope of the present disclosure.

FIG. 1 shows a prior art three junction multijunction solar cell along with an ARC.

FIG. 2 shows the refractive index for four materials.

FIGS. 3A-3C show embodiments of the present invention.

FIG. 4 shows the simulated reflectivity of two embodiments of the invention compared with that of a standard two-layer ARC.

FIG. 5 shows the measured reflectivity of one embodiment of the invention on a 3-junction multijunction solar cell.

FIGS. 6A-6D show the angle of acceptance comparison of the five-layer ARC (solid) vs. the two-layer ARC.

FIGS. 7A and 7B show Pourbaix diagrams for Al and Si illustrating the higher stability of SiO₂ in solutions of pH<9.5.

FIG. 8 shows the reflectivity changes when unprotected two-layer ARC is subjected to varying soak times in high pH developer solution.

FIG. 9 shows reflectivity rises in the visible region when five-layer ARC is subjected to a 400° C. thermal anneal.

FIG. 10 shows a high resolution TEM illustrating presence of amorphous InAlP oxide layer between the InAlP widow layer and the deposited TiO₂.

FIG. 11 shows simulated reflectivity spectra for multi junction solar cells with two different anti-reflection coating designs.

FIG. 12 shows the normalized short circuit current (Isc) as a function of the incident light angle for a multijunction solar cell device with two different anti-reflection coating designs.

FIG. 13 shows measured reflectivity spectra for multi junction solar cells with two different ant-reflection coating designs on glass-incident media.

FIG. 14 shows measured reflectivity spectra for multi junction solar cells with two different anti-reflection coating designs.

FIG. 15 shows measured reflectivity spectra for a multi junction solar cell having a three-layer TiO₂/Ta₂O₅/Al₂O₃ ARC and for a multi junction solar cell with a conventional two-layer ARC.

Reference is now made to certain embodiments of methods and apparatus of the present invention. The disclosed embodiments are not intended to be limiting of the claims. To the contrary, the claims are intended to cover all alternatives, modifications, and equivalents.

### DETAILED DESCRIPTION

The present invention relates to antireflection coatings for multijunction solar cells with two, three, four, five or six junctions. The inventive ARC design includes depositing multiple layers of high, medium, and low refractive index materials with particular, varying physical thicknesses and also with varying ¼wavelength optical thicknesses, on top of the window layer of a multijunction solar cell.

Examples of five-layer ARC designs of the current invention that depend on the window layer beneath the ARC, are listed below:
(1) Window layer/High refractive index/low refractive index/high refractive index/medium refractive index/with final SiO₂ protective layer or without/encapsulant;
(2) Window layer/High refractive index/medium refractive index/low refractive index/high refractive index/low refractive index/with final SiO₂ protective layer or without/encapsulant;
(3) Window layer/High refractive index/low refractive index/high refractive index/low refractive index/medium refractive index/low refractive index/with final SiO₂ protective layer or without/encapsulant; and
(4) Window layer/High refractive index/medium refractive index/high refractive index/medium refractive index/with final SiO₂ layer or without/encapsulant.

It should be noted that the listed examples of layer combinations above can be extended to include more layers than those described, and the above examples are meant to be illustrative and not limiting. Alternative embodiments of the inventive ARC with more than five layers may be used, such as a nine-layer ARC. In some cases, a “medium” refractive index material can be made by applying multiple layers of different materials to achieve a multilayer material with a “medium” refractive index. For example, a nine-layer ARC may be:
(1) Window layer/High refractive index/low refractive index/high refractive index/low refractive index/medium refractive index/low refractive index/high refractive index/low refractive index/with final SiO₂ protective layer or without/encapsulant; and
(2) Window layer/High refractive index/low refractive index/high refractive index/low refractive index/medium refractive index/low refractive index/medium refractive index/low refractive index/with final SiO₂ protective layer or without/encapsulant.

The window layer, comprised of InAlP or AlGaAs, or a partially oxidized window layer, on the upper most subcell of the multijunction solar cell is directly beneath the multilayer ARC. As stated, the thicknesses of an ARC design depend on the top window layer material composition and thickness above the top subcell. In an embodiment of the invention, this top window layer may be comprised of InAlP, or in another embodiment comprised of AlGaAs, with a thickness of approximately 20 nm to 40 nm with a thickness of about 33 nm and may be grown by molecular beam epitaxy or by metal organic chemical vapor deposition.

The ARC may be applied below an encapsulant, such as a glass coverslip or a glass secondary optical element, which are used to protect or focus light onto the multijunction solar cell, respectively. The encapsulant is considered to be the media directly adjacent to the solar cell with an optically infinite thickness and known refractive index. If the encapsulant is adhered to the solar cell with an optical adhesive such as silicone, it is considered to be optically equivalent to the encapsulant as such having the same refractive index as that of the encapsulant. If no encapsulant is used, then the adjacent material is assumed to be air with a refractive index of n=1. It should be noted that it is known in the art that functional solar cells use an encapsulant, but the use of an encapsulant is not meant to be limiting in the scope of this invention.

The ARC may be sealed by an optically inactive coating of SiO₂, herein referred to as a “final protective layer”. The final protective SiO₂ layer nominally has the same refractive index as the encapsulant, thereby ensuring the layer is optically inactive. SiO₂ is also a material used as an optically active ARC layer in some embodiments of the invention. In the case where there is no attached encapsulant material, the final protective SiO₂ layer will be optically active and its thickness can be adjusted to account for the lack of encapsulant material. In this ARC design, the layers are deposited in order to distribute the refractive indices of the materials at varying thicknesses.

The “high refractive index material” in one layer of the ARC can be selected to have a lower refractive index than that of the window layer below the ARC. This window layer can be InAlP, GaP, AlGaAs, or partially oxidized InAlP, GaP, or AlGaAs. The “low refractive index material” in another layer of the ARC can be selected to have an equal or higher refractive index than that of the optical glass encapsulant. If no encapsulant is used, the ARC design is “air matched”, and the low refractive index material layer in the ARC is higher than the refractive index n=1.

In certain embodiments, the high refractive index material, considering the epitaxial semiconductor material used in the multijunction solar cell and the encapsulant, is a material with a refractive index above n=2 at a wavelength of approximately 500 nm. The low refractive index material, considering the epitaxial semiconductor material used in the multijunction solar cell and the encapsulant, is a material with an index above n=1 and below n=2 at a wavelength of approximately 500 nm. A medium refractive index material would have an index between the high and low refractive indices.

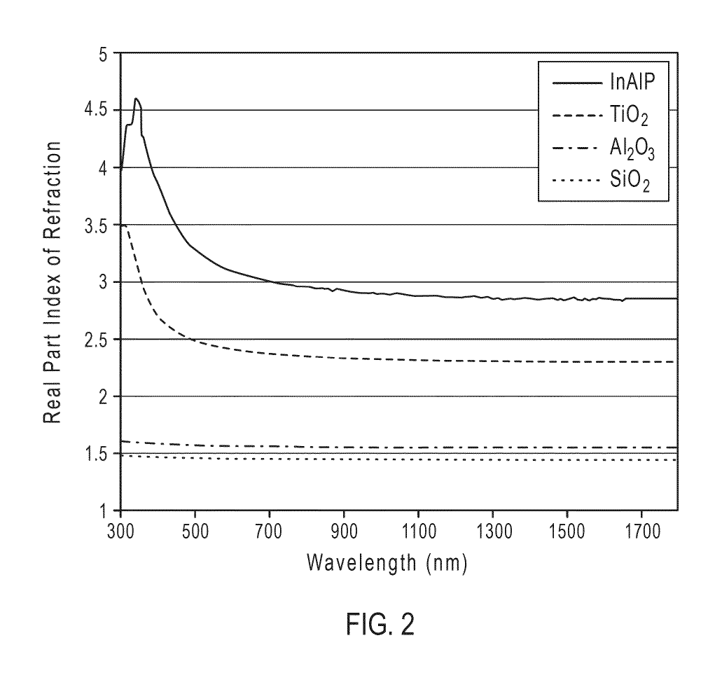

High refractive index materials include, for example, TiO₂, ZnS, SiC, ZnO, ZrO₂, ZnSe, ZnS, LiNbO₃, and LiTaO₃. A material with a refractive index between that of the high and low refractive index materials that can be used as a medium index layer for the high-low ARC design includes, for example, CeF₃, TaO₅, Si₃Nₓ, or Al₂O₃. Low refractive index materials includes, for example, CaF₂, BaF₂, SiO₂, or MgF. SiO₂ is a key material used as a low-index layer in many of the preferred embodiments of the invention. Several materials can be used, as those skilled in the art are aware, to create the alternating system of refractive indices for material layers and should not be limited to those listed here. Some of these, which are not listed above, include, for example, SiO, HfO₂, Y₂O₃, Sc₂O₃, La₂O₃, GaN, etc. FIG. 2 shows the wavelength-dependent refractive index for a few materials that may be used in the present invention.

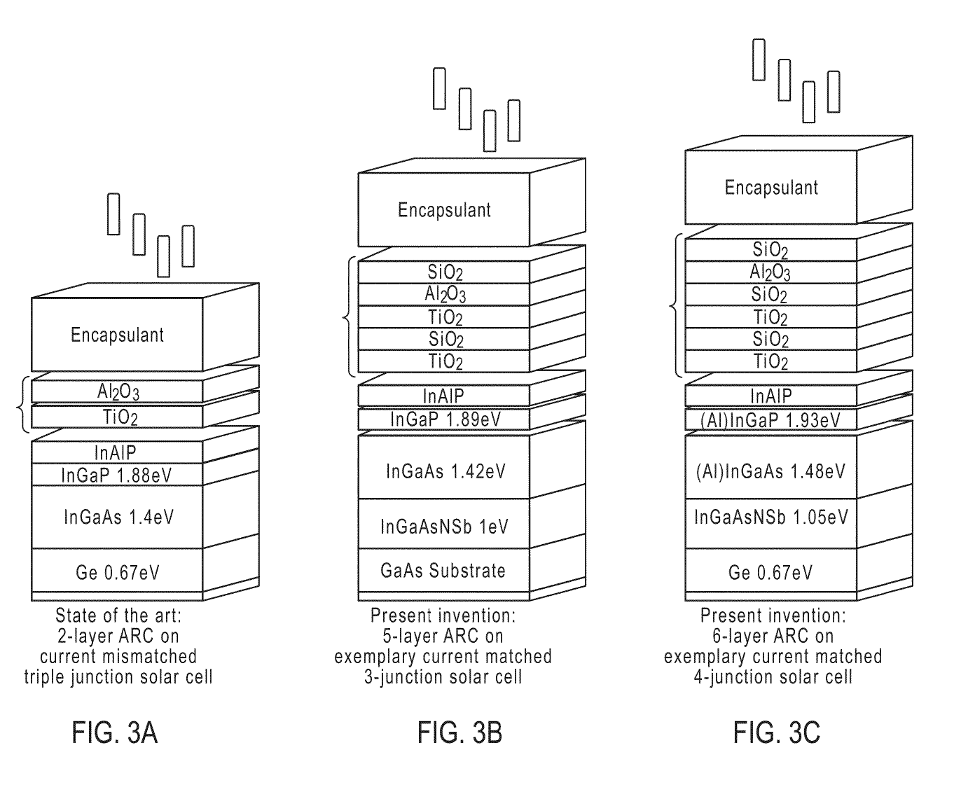

FIGS. 3A-3C shows the structure of certain embodiments of the invention, all with a SiO₂ protective final layer, on a current matched 3- or 4-junction solar cell (FIG. 3B and FIG. 3C) compared to the current art two-layer ARC on a current mismatched solar cell (FIG. 3A). In these embodiments, the five-layer and six-layer ARC can be created from depositing several different materials with difference refractive indices, a high refractive index (TiO₂), and medium refractive index (Al₂O₃), a low refractive index material (SiO₂).

An embodiment of the invention is provided in Table 1b, where the five-layer ARC has an inverted refractive index layer pair, Layers 2 and 3 where Layer 2 has a higher refractive index than Layer 3, within the layer stack that have an effective ¼wavelength optical thickness shifted towards the ultraviolet region of the solar spectrum. Additionally, the ¼wavelength optical thickness of the surrounding layers, Layers 1 and 4, have longer ¼wavelength optical thicknesses of 570 nm. The net result of this embodiment is an ARC that offers dramatically reduced reflections over a wider wavelength range than a two-layer ARC. The entire ARC, layers 1-5, uses a high/low/high/medium/low refractive index design, wherein TiO₂ is the layer with high refractive index, Al₂O₃ is the layer with medium refractive index, and SiO₂ is the layer with low refractive index. An alternative embodiment of this invention can be made without Layer 5, the final protective layer. These layers can be deposited by electron beam evaporation. Of note, the thickness of each layer can be adjusted by +/−2.5 nm of the thicknesses listed below, and in some cases +/−7.5 nm to result in approximately the same high performance ARC design.

TABLE 1b
Embodiments of the Invention with Encapsulant

| | Layer | Layer | Layer | Layer | Layer | Layer | Encap- |
|---|---|---|---|---|---|---|---|
| | 0 | 1 | 2 | 3 | 4 | 5 | sulant |
| Physical | 33 nm | 58 nm | 28 nm | 16 nm | 90 nm | 20 nm | — |
| Thickness | | | | | | | |
| Material | InAlP | TiO₂ | SiO₂ | TiO₂ | Al₂O₃ | SiO₂ | SiO₂ |
| Wavelength | — | 570 nm | 350 nm | | 570 nm | — | — |
| corresponding | | | | | | | |
| to ¼ | | | | | | | |
| wavelength | | | | | | | |
| optical | | | | | | | |
| thickness | | | | | | | |

An alternate embodiment of a five-layer ARC is provided in Table 1c that has an inverted refractive index layer pair, Layers 2 and 3, within the layer stack that have an effective ¼wavelength optical thickness shifted towards the ultraviolet region of the solar spectrum. Additionally, the ¼wavelength optical thickness of the surrounding layers, Layers 1 and 4, have longer ¼wavelength optical thicknesses of 570 nm. The ARC layers include alternating refractive index materials, TiO₂, Al₂O₃, and SiO₂ in the order of TiO₂/Al₂O₃/TiO₂/Al₂O₃/SiO₂ on top of the widow layer and below the encapsulant. These four layers of TiO₂/Al₂O₃/TiO₂/Al₂O₃ can be deposited by electron beam evaporation. An additional, fifth layer may be applied to the top Al₂O₃ layer comprised of SiO₂ but is not restrictive, and an alternate embodiment of the ARC can be made without Layer 5.

TABLE 1c
Exemplary Embodiment of the Invention with Encapsulant

| | Layer | Layer | Layer | Layer | Layer | Layer | Encap- |
|---|---|---|---|---|---|---|---|
| | 0 | 1 | 2 | 3 | 4 | 5 | sulant |
| Physical | 33 nm | 58 nm | 32 nm | 16 nm | 90 nm | 20 nm | — |
| Thickness | | | | | | | |
| Material | InAlP | TiO₂ | Al₂O₃ | TiO₂ | Al₂O₃ | SiO₂ | SiO₂ |
| Wavelength | — | 570 nm | 375 nm | | 570 nm | — | — |
| corresponding | | | | | | | |
| to ¼ | | | | | | | |
| wavelength | | | | | | | |
| optical | | | | | | | |
| thickness | | | | | | | |

Another embodiment is provided in Table 1d, where the six-layer ARC employs two sets of inverted refractive index layer pairs, Layers 2-3, and Layers 4-5, the second pair having an effective ¼wavelength optical thickness that matches that of the first layer. However, the first pair has an effective ¼wavelength optical thickness that is shifted towards the ultraviolet region of the solar spectrum. The ARC layers comprise alternating refractive index materials, TiO₂, Al₂O₃, and SiO₂ in the order of TiO₂/SiO₂/TiO₂/SiO₂/Al₂O₃/SiO₂ on top of the widow layer and below the encapsulant. These five layers of TiO₂/SiO₂/TiO₂/SiO₂/Al₂O₃ can be deposited by electron beam evaporation. An additional, sixth layer may be applied to the top Al₂O₃ layer comprised of SiO₂ but is not restrictive, and an alternate embodiment of the ARC can be made without Layer 6.

TABLE 1d
Embodiment of the Invention with Encapsulant

| | Layer 0 | Layer 1 | Layer 2 | Layer 3 | Layer 4 | Layer 5 | Layer 6 | Encapsulant |
|---|---|---|---|---|---|---|---|---|
| Solar Cell | 33 nm | 56 nm | 30 nm | 19 nm | 30 nm | 60 nm | 20 nm | SiO₂ |
| | InAlP | TiO₂ | SiO₂ | TiO₂ | SiO₂ | Al₂O₃ | SiO₂ | |
| Wavelength | — | 550 nm | 375 nm | | 550 nm | | — | — |
| corresponding | | | | | | | | |
| to ¼ | | | | | | | | |
| wavelength | | | | | | | | |
| optical | | | | | | | | |
| thickness | | | | | | | | |

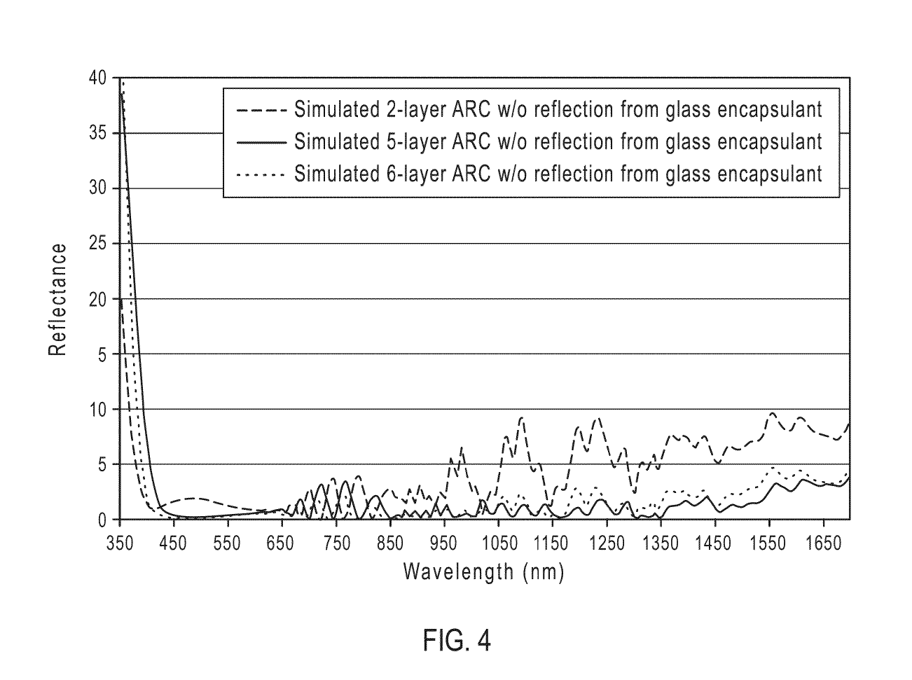

FIG. 4 shows simulated reflectivity of a standard two-layer ARC design on a three-junction solar cell compared to that of a five-layer and six layer ARC design.

Table 2 shows the calculated improvement of the above design through current gain over the industry two-layer ARC design for a three junction multijunction solar cell. As indicated in the final column labeled as “Total”, an inverted five-layer ARC improves overall current significantly, over 1.7%, compared to a current-art two-layer ARC. A six-layer ARC also improves the overall current by over 1.7%.

TABLE 2
Current gain using the inverted pair five-layer and six-layer
ARC versus two-layer ARC for a three-junction solar cell.

| | | J1 | | J2 | | J3 | | Total |
|---|---|---|---|---|---|---|---|---|
| 3J | Bandgap | 1.885 | eV | 1.412 | eV | 0.961 | eV | |
| | 2-Layer Jsc | 14.0 | mA/cm² | 14.0 | mA/cm² | 15.0 | mA/cm | 43.00 mA/cm² |
| | 3-Layer Jsc | 14.13 | mA/cm² | 14.12 | mA/cm² | 15.51 | mA/cm² | 43.76 mA/cm² |
| | 4-Layer Jsc | 14.12 | mA/cm² | 14.15 | mA/cm² | 15.50 | mA/cm² | 43.76 mA/cm² |

The current gain is made even more significant when comparing the present invention to current state of the art two-layer ARC designs when the number of subcells in the multijunction solar cell is increased. Table 3 shows the calculated current gain using the five-layer ARC design as listed in Table 1c and Table 1d compared to a standard two-layer ARC design in Table 1a for a four junction multijunction solar cell. As indicated in Table 3, a five-layer ARC design exhibits an improvement of slightly over 1.95% for a four junction multijunction solar cell. As expected, significant improvements, i.e., over 4% current gain, are made in J4 of the solar cell using an inverted 5 and six-layer ARC design compared to the two-layer ARC design.

TABLE 3
Current gain using an inverted pair five-layer and inverted triplet
six-layer ARC versus two-layer ARC for a four junction solar cell.

| | | J1 | | J2 | | J3 | | J4 | | Total | |
|---|---|---|---|---|---|---|---|---|---|---|---|
| 4J | Bandgap | 1.934 | eV | 1.479 | eV | 1.06 | eV | 0.67 | eV | | |
| | 2-Layer Jsc | 12.82 | mA/cm² | 12.81 | mA/cm² | 12.79 | mA/cm² | 12.82 | mA/cm² | 51.25 | mA/cm² |
| | 5-Layer Jsc | 12.98 | mA/cm² | 12.86 | mA/cm² | 13.08 | mA/cm² | 13.34 | mA/cm² | 51.25 | mA/cm² |
| | 6-Layer Jsc | 12.96 | mA/cm² | 12.87 | mA/cm² | 13.08 | mA/cm² | 13.32 | mA/cm² | 52.23 | mA/cm² |

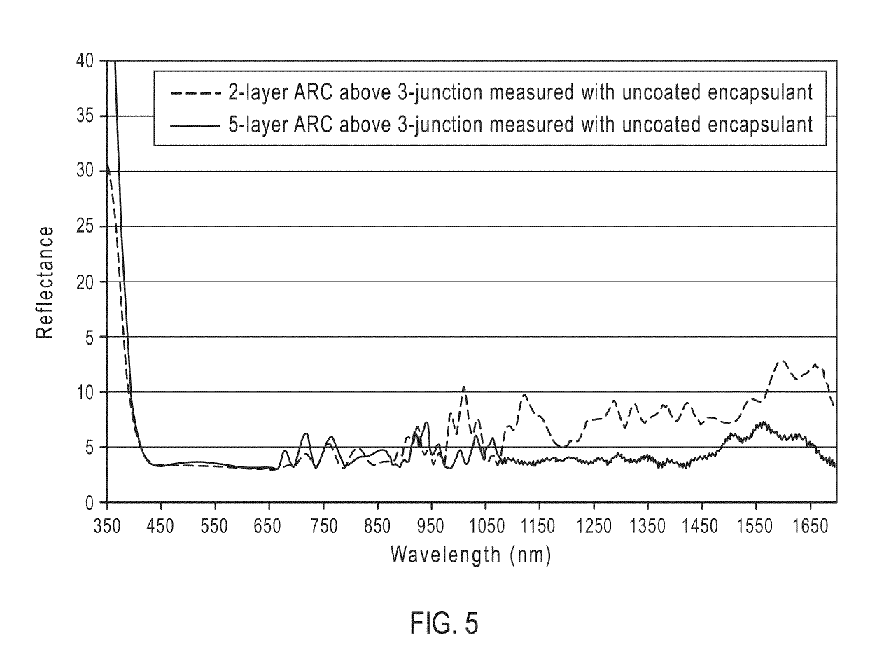

To determine the efficacy of a greater than two-layer ARC, reflectivity measurements were conducted on one of the inventive ARC designs compared to a standard two-layer ARC design for a three junction dilute nitride solar cell. FIG. 5 shows this measurement, which agrees with simulated results. FIG. 5 shows the reflectance for a five-layer and a two-layer ARC with an adhered optical encapsulant. The dilute nitride subcell in this three junction multijunction solar cell is a GaInNAsSb subcell, which absorbs light in the infrared region, above 880 nm. Further, an encapsulant, comprised of silicone, was adhered to the top of the ARC. The non-zero reflectance, approximately 3%, is due to light that is reflected from the surface of the encapsulant. This can be further reduced with the addition of an ARC on top of the encapsulant, such as a thin layer of MgF₂.

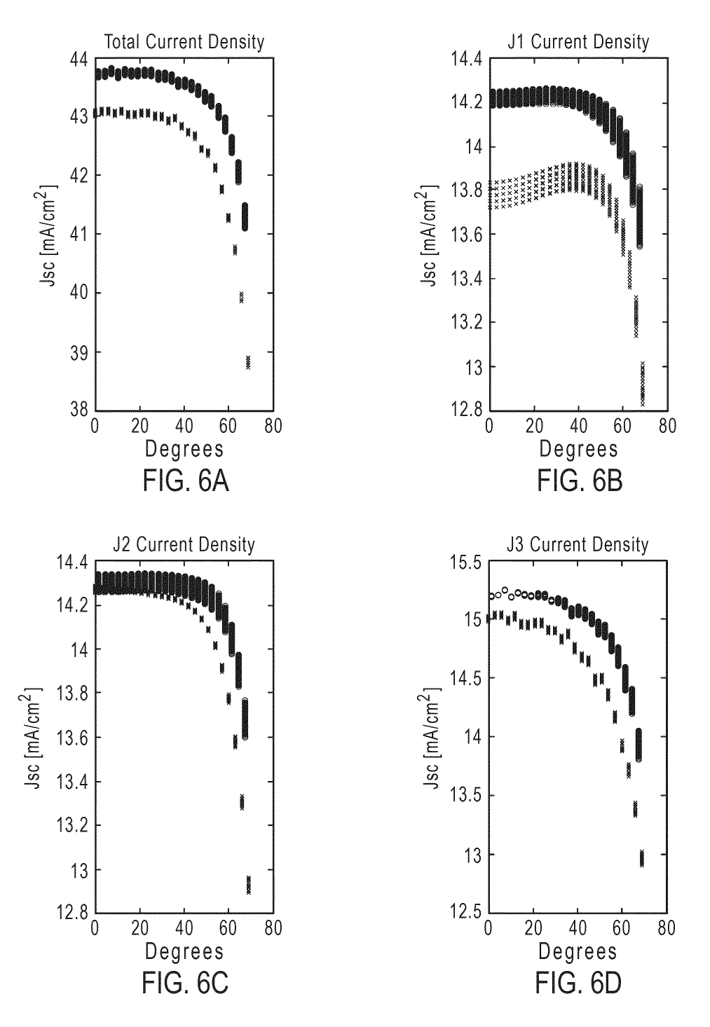

As discussed, an additional performance factor of ARC designs is reflectivity of light at non-direct incident angles, e.g., non-orthogonal to the uppers surface of the solar cell. That is, an important feature of ARCs is that reflectivity remains low while the incident angle increases from 0 degrees to 90 degrees. Certain embodiments of the present invention using the 5- and six-layer ARC are configured to have significant gains over a prior art two-layer ARC when the angle of light is varied. FIGS. 6A-6D show a plot of calculated performance of an embodiment of the five-layer ARC (solid) compared to the two-layer ARC versus incident angle. Each layer assumes up to a +/−2 nm error in layer thickness. FIGS. 6A-6D show that the total current and all three subcell currents have significantly higher acceptance angle performance with the five-layer ARC compared to the two-layer ARC. The same is observed with the six-layer ARC.

The subcells in the multijunction solar cell with the above-described ARC designs may include one or more lattice matched subcells, which include, for example, tunnel junctions, a front surface field (FSF) or window layer, an emitter, a depletion region, base and/or a back surface field. Semiconductor materials used in these subcells may include, for example, indium gallium phosphide, indium phosphide, gallium arsenide, aluminum gallium arsenide, indium gallium arsenide, germanium and dilute nitride compounds such as GaInNAsSb, GaInNAsBi, GaInNAsSbBi, GaNAsSb, GaNAsBi, GaNAsSbBi, or a combination of any of the foregoing. For ternary and quaternary compound semiconductors, a wide range of alloy ratios can be used.

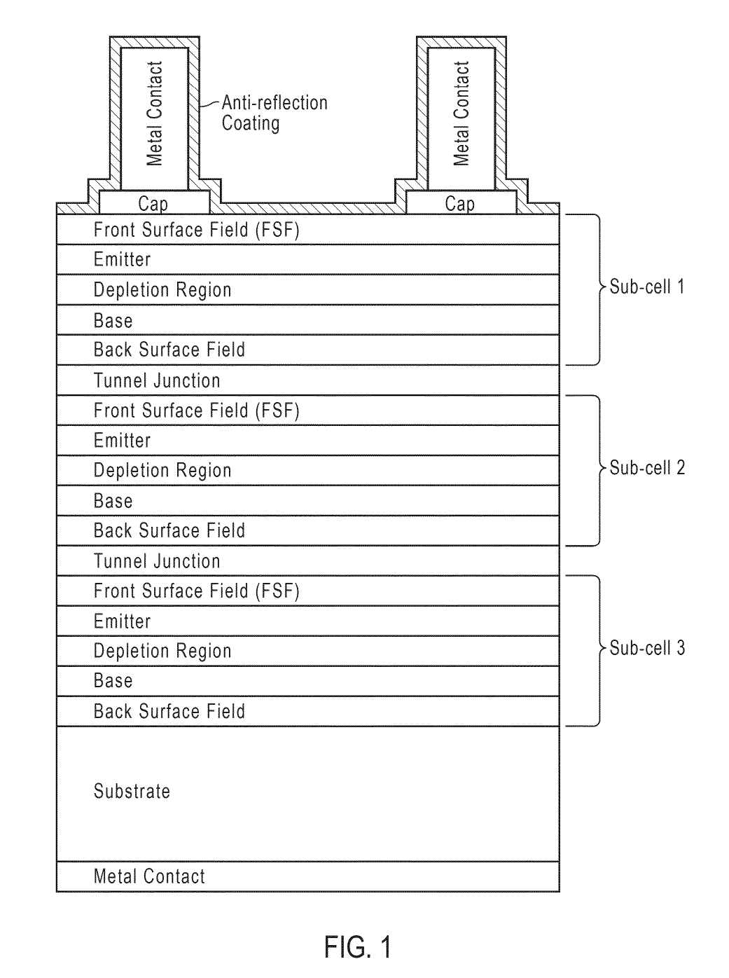

Certain embodiments of a three junction multijunction solar cell with the above-described ARC design, grown on a GaAs substrate, comprise an InGaP top subcell with a band gap between 1.84 eV and 1.91 eV and a front surface field (FSF) comprising InAlP. InAlP acts as a passivation layer for the InGaP subcell and prevents efficiency-reducing absorption of the spectrum into the top InGaP subcell. An example of this structure is shown in FIG. 1, where top subcell (subcell 1) is defined as the subcell closest to the cap below the metal contact and ARC, the middle subcell is defined as the subcell below the top subcell (subcell 2), which is above the bottom subcell (subcell 3). In certain embodiments of a three junction multijunction solar cell, the InGaP top subcell has a band gap of 1.88 eV. Certain embodiments of a three junction multijunction solar cell may comprise a GaAs middle subcell. In certain embodiments, the GaAs middle subcell has a band gap of 1.415 eV. Another embodiment of a three junction multijunction solar cell may comprise a GaInAsNSb bottom subcell with a band gap between 0.85 eV and 1 eV, and in certain embodiments, a band gap of 0.965 eV. All subcells in a three-junction multijunction solar cell may be lattice matched to the substrate and to one another.

Certain embodiments of a three junction multijunction solar cell, with the above-described ARC design, grown on Ge, comprise a InGaP or AlInGaP top subcell with a band gap between 1.84 eV to 2.1 eV and a FSF comprising InAlP. Certain embodiments of a three-junction multijunction solar cell may comprise a GaAs, AlGaAs, or GaInAs middle, or second, subcell, below the top subcell. In certain embodiments, the middle subcell has a band gap of between 1.4 eV and 1.5 eV. A three junction multijunction solar cell may comprise a bottom GaInAsNSb subcell with a band gap between 0.85 eV and 1 eV. All subcells are lattice matched to the substrate and to one another.

Certain embodiments of a four junction multijunction solar cell, with the above-described ARC design, grown on Ge, comprise a InGaP or AlInGaP top subcell with a band gap between 1.84 eV and 2.12 eV and a FSF comprising InAlP. The subcell below the top subcell, or second subcell, may comprise AlGaAs, GaAs, or GaInAs with a band gap between 1.4 eV and 1.65 eV. The third subcell, which is below the second subcell, may comprise GaInAsNSb with a band gap between 1 eV and 1.26 eV. The fourth and bottom-most subcell may comprise GaInAsNSb with a band gap between 0.85 eV and 1 eV. All subcells are lattice matched to the substrate and to one another.

Another embodiment of a four junction multijunction solar cell, with the above-described ARC design, grown on Ge, comprises a InGaP or AlInGaP top subcell with a band gap between 1.84 eV and 2.12 eV and a FSF comprising InAlP. The subcell below the top subcell, or second subcell, may comprise AlGaAs, GaAs, or GaInAs with a band gap between 1.4 eV and 1.65 eV. The third subcell, which is below the second subcell, may comprise GaInAsNSb with a band gap between 0.9 eV and 1.26 eV. The fourth and bottom-most subcell may comprise Ge with a band gap of 0.68 eV. All subcells are lattice matched to the substrate and to one another.

Additional embodiments of five and six junctions using dilute nitrides and GaAs or Ge substrates can also be used with the ARC design.

The five and six-layer ARC disclosed herein can be formed by depositing the ARC layers via electron beam evaporation at high energies for better film quality of each layer. The five and six-layer ARC can also be formed through ion beam deposition, which involves ion sputtering of one material, such as Ti, and reacting the species with oxygen, which is subsequently deposited as TiO₂ on the solar cell wafer. An additional method for forming the ARC disclosed here can be by radio frequency (RF) sputtering, a technique which uses RF waves to create a highly energetic plasma from an inert gas, such as Argon, which physically removes a material, such as TiO₂, from a target source and deposits the material onto a solar cell wafer.

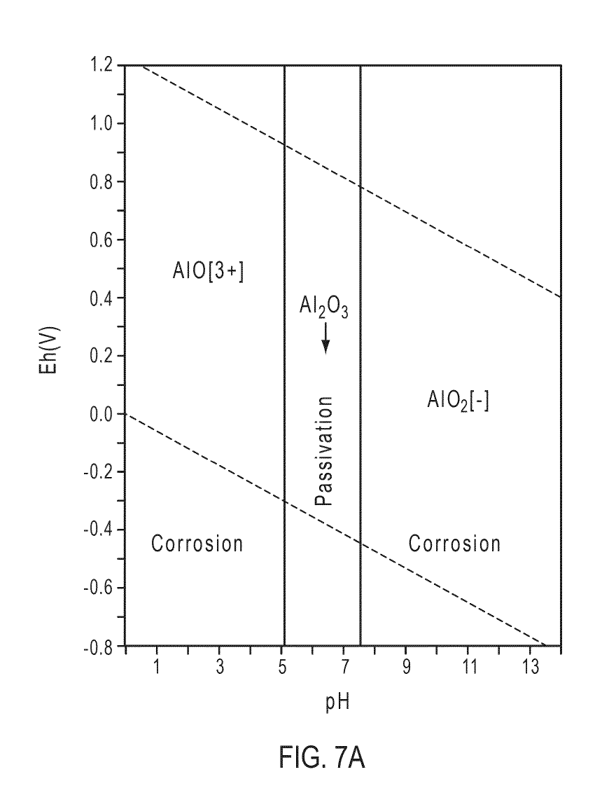

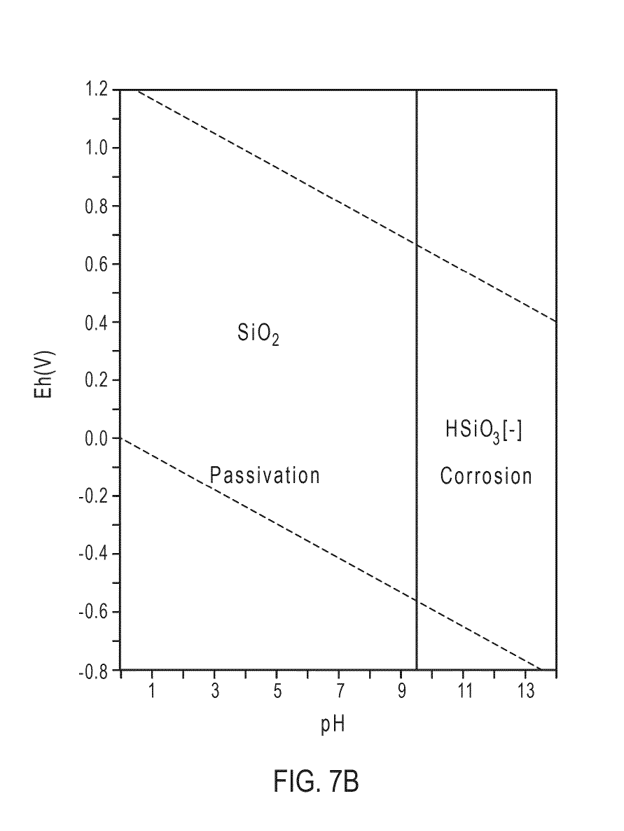

The embodiments include multiple layers ARCs with and without a protective SiO₂ layer beneath the SiO₂ encapsulant. In certain embodiments, ARCs must be able to withstand acidic and basic aqueous environments during processing without decomposing. Some materials that are suitable for use in ARC designs for multijunction solar cells described above, such as TiO₂, Al₂O₃, and SiO₂ decompose to some degree in non-neutral pH environments, and so the approximately 20 nm thick SiO₂ layer added below the encapsulant protects the ARC by preventing decomposition during processing. FIGS. 7A and 7B show Pourbaix diagrams of Al₂O₃ and SiO₂, illustrating the improved etch resistance of SiO₂ in solutions up to pH 9.5.

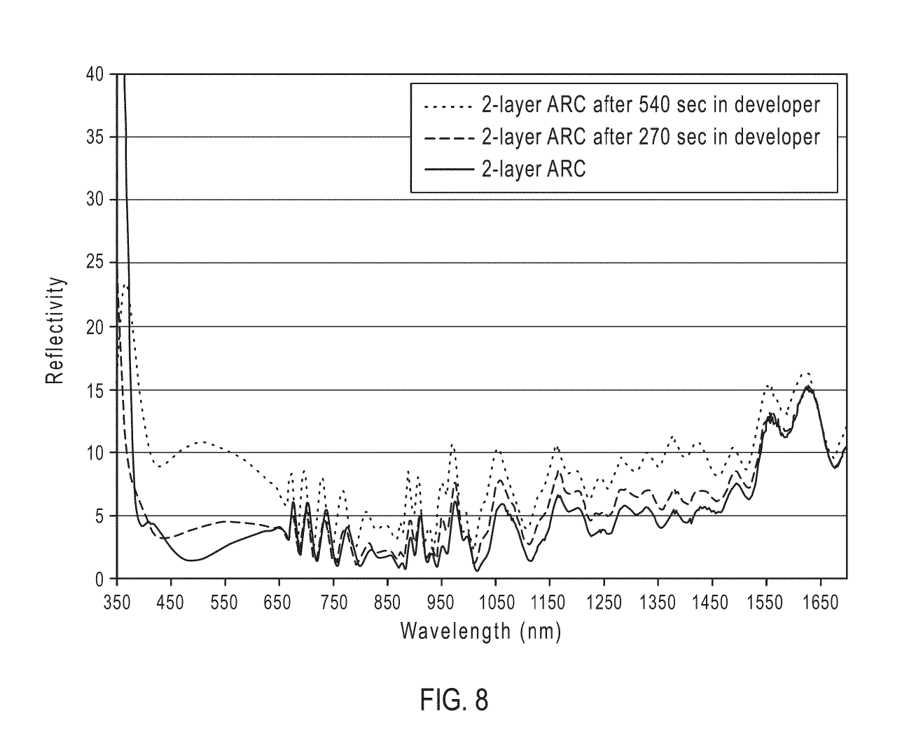

FIG. 8 illustrates the measured change in reflectivity that is possible when a conventional two-layer ARC decomposes in a high pH environment without the SiO₂ layer. The measurements were made without an encapsulant attached to the cell. Without this protective layer, the Al₂O₃ decomposes in the basic solution and results in a dramatically higher reflectivity as indicated by the dotted lines in the figures.

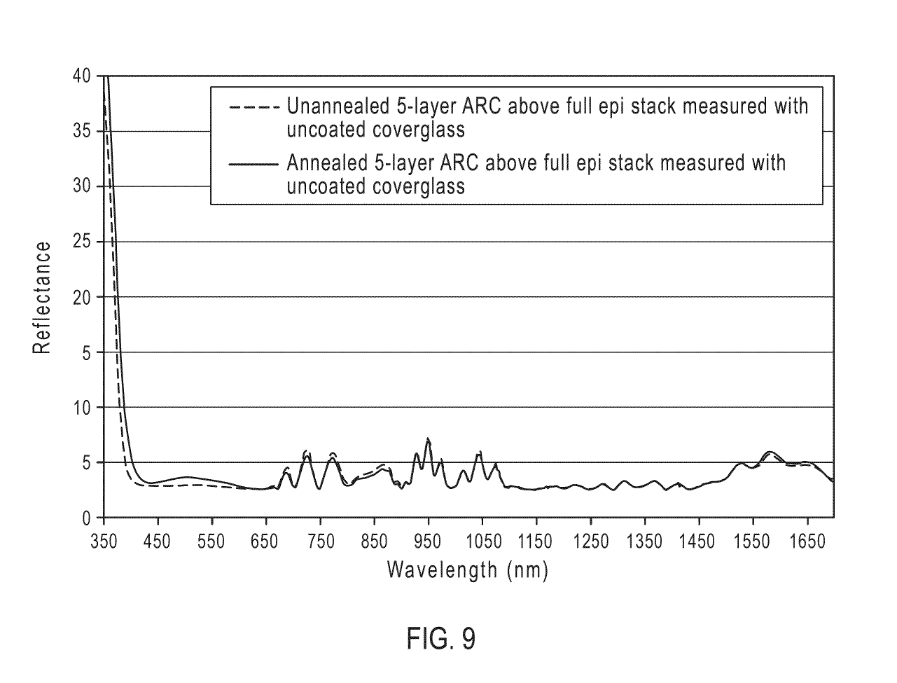

The present invention can also be configured to withstand thermal annealing during processing, which may be between temperatures of 250° C. to 425° C. It can be verified through ellipsometry measurements that the reflectivity of the ARC post-anneal increases due to a lowering of refractive index of the Al₂O₃ and TiO₂ layers. The inventive design accounts for this small change and thicknesses of the ARC layers are designed so as to minimize the additional reflection incurred at wavelengths less than 600 nm. FIG. 9 shows the minimal increase of reflectivity due to thermal annealing of an inventive ARC. As shown in FIG. 9, the reflectivity increases in the visible region when a five-layer ARC is subjected to a 400° C. thermal anneal. The measurements were taken with an optical encapsulant adhered to the cell.

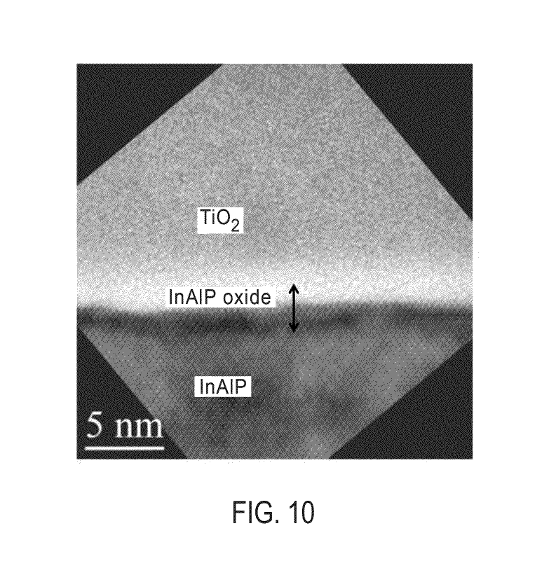

Materials used in window layers beneath the inventive ARC, and in some cases used in prior art ARCs, such as InAlP, are highly reactive during the deposition and annealing process of the ARC. Depending on the temperature of the anneal, this window layer has been shown to oxidize, creating a thin layer of InAlPOₓ of approximately 3 nm to 4 nm between the InAlP FSF and the bottom-most layer of the ARC, shown in FIG. 10. FIG. 10 shows a high-resolution TEM illustrating the presence of an amorphous InAlP oxide layer between the InAlP window layer and the deposited TiO₂ layer. Certain embodiments of the ARC design can be configured to account for this oxidation and thinning that occurs during cell processing.

ARCs provided by the present disclosure can include at least one inverted refractive index pair. In certain embodiments, an inverted refractive index pair comprises an upper layer comprising a first material characterized by a first refractive index and a first thickness; and a lower layer comprising a second material characterized by a second refractive index and a second thickness, wherein the upper layer overlies the lower layer, and the first refractive index is higher than the second refractive index. The total thickness of the refractive index pair including the upper and lower layers can be optimized for the same ¼wavelength optical thickness. An ARC can include one or more layers above the inverted refractive index pair and/or one or more layers below the refractive index pair. The ¼wavelength optical thickness of different layers within the ARC may be optimized for different wavelengths. In certain embodiments, the ¼wavelength optical thickness of the inverted refractive index pair is optimized for a first wavelength and other layers can be optimized for a second wavelength. In certain embodiments, the first wavelength is shorter than the second wavelength.

An ARC can include a second or more inverted refractive index pairs. The second refractive index pair can be optimized for the same or different wavelength than the other refractive index pairs.

In certain embodiments, an anti-reflection coating comprises at least one inverted refractive index pair, wherein the at least one inverted refractive index pair comprises an upper layer comprising a first material characterized by a first refractive index and a first thickness; and a lower layer comprising a second material characterized by a second refractive index and a second thickness, wherein the upper layer overlies the lower layer, and the first refractive index is higher than the second refractive index.

In certain embodiments of an ARC, a total thickness of the upper layer and the lower layer represents a ¼wavelength optical thickness at a wavelength from about 300 nm to 425 nm.

In certain embodiments of an ARC, a total thickness of the upper layer and the lower layer represents a ¼wavelength optical thickness at a wavelength from about 325 nm to 400 nm.

In certain embodiments of an ARC, a total thickness of the upper layer and the lower layer is from about 20 nm to about 200 nm.

In certain embodiments of an ARC, the first material comprises TiO₂ and the second material is selected from SiO₂ and Al₂O₃.

In certain embodiments of an ARC, the first material comprises Al₂O₃ and the second material comprises SiO₂.

In certain embodiments, an ARC comprises one or more layers comprising a material characterized by a refractive index lower than the first refractive index overlying the at least one inverted refractive index pair.

In certain embodiments, an ARC comprises one or more layers comprising a material characterized by the first refractive index beneath the at least one inverted refractive index pair.

In certain embodiments of an ARC, the anti-reflection coating is characterized by a transmission of about 100% and a reflection of less than about 5% from 400 nm to 1700 nm.

In certain embodiments of an ARC, the first refractive index is greater than 2 at a wavelength of about 500 nm; and a second refractive index from 1 to 2 at a wavelength of approximately 500 nm.

In certain embodiments of an ARC, the first refractive index is greater than 1.5 at a wavelength of about 500 nm; and the second refractive index from 1 to 1.5 at a wavelength of approximately 500 nm.

In certain embodiments of an ARC, the first material is selected from TiO₂, ZnS, SiC, ZnO, ZrO₂, ZnSe, ZnS, LiNbO₃, and LiTaO₃; and the second material is selected from CaF₂, BaF₂, SiO₂, and MgF.

In certain embodiments of an ARC, the first material is selected from TiO₂, ZnS, SiC, ZnO, ZrO₂, ZnSe, ZnS, LiNbO₃, and LiTaO₃; and the second material is selected from CeF₃, TaO₅, SiN_{X}, and Al₂O₃.

In certain embodiments of an ARC, the first material is selected from CeF₃, TaO₅, SiN_{X}, and Al₂O₃; and the second material is selected from CaF₂, BaF₂, SiO₂, and MgF.

In certain embodiments of an ARC, the at least one inverted index pair is characterized by a ¼wavelength thickness at a first wavelength; and the anti-reflection coating comprises at least one layer overlying the inverted index pair comprising a material characterized by a refractive index lower than the first refractive index and a ¼wavelength thickness at a second wavelength, wherein the first wavelength and the second wavelength are different.

In certain embodiments of an ARC, the second wavelength is longer than the first wavelength.

In certain embodiments of an ARC, the first wavelength is from about 325 nm to about 425 nm and the second wavelength is from about 520 nm to about 630 nm.

In certain embodiments of an ARC, the inverted index pair is characterized by a ¼ wavelength thickness at a first wavelength; and the at least one inverted index pair overlies at least one third layer, wherein the at least one third layer comprises a material characterized by a refractive index higher than the second refractive index and a ¼wavelength thickness at a second wavelength, wherein the first wavelength and the second wavelength are different.

In certain embodiments of an ARC, the second wavelength is longer than the first wavelength.

In certain embodiments of an ARC, the first wavelength is from about 325 nm to about 425 nm and the second wavelength is from about 520 nm to about 630 nm.

In certain embodiments, an ARC comprises a first refractive index pair and a second refractive index pair overlying the first refractive index pair.

In certain embodiments of an ARC, wherein the first inverted index pair is characterized by a ¼wavelength thickness at a first wavelength; and the second inverted index pair is characterized by a ¼wavelength thickness at a second wavelength.

In certain embodiments of an ARC, the second wavelength is longer than the first wavelength.

In certain embodiments of an ARC, the first wavelength is from about 325 nm to about 425 nm and the second wavelength is from about 520 nm to about 630 nm.

In certain embodiments, an ARC comprises at least one third layer comprising a material characterized by a third material characterized by a refractive index higher than the second refractive index and a ¼wavelength thickness at a third wavelength.

In certain embodiments of an ARC, the first wavelength is from about 325 nm to about 425 nm and the third wavelength is from about 520 nm to about 630 nm.

In certain embodiments of an ARC, the reflectance at wavelengths from 450 nm to 1700 nm at an incident angle of 0 degrees (normal) is less than 5%.

In certain embodiments of an ARC, the reflectance at wavelengths from 450 nm to 1700 nm at an incident angle of 60 degrees is less than 10%.

In certain embodiments, a protective layer overlies the anti-reflection coating.

In certain embodiments, the protective layer comprises SiO₂.

In certain embodiments, the anti-reflection coating overlies a multijunction solar cell. An ARC provided by the present disclosure may also be used in other applications in which low reflectivity over a broad wavelength range is desired.

In certain embodiments of an ARC, the multijunction solar cell comprises a window layer and the anti-reflection coating overlies the window layer. A window layer may comprise a material selected from InAlP, GaP, AlGaAs, oxidized InAlP, oxidized GaP, and oxidized AlGaAs. A window layer may be characterized by a thickness from 20 nm to 40 nm.

In certain embodiments, an encapsulant overlies the anti-reflection coating.

In certain embodiments, a protective layer overlying the anti-reflection coating. In certain embodiments, a protective layer comprises a material having a refractive index of about 1.5.

In certain embodiments, an ARC comprises a first layer comprising a first material characterized by a first refractive index and by a first thickness; an inverted refractive index pair overlying the first layer, wherein the inverted refractive index pair comprises a second layer comprising a material characterized by a second refractive index and by a second thickness; and a third layer comprising a material characterized by a third refractive index and by a third thickness; and a fourth layer comprising a material characterized by a fourth refractive index and a fourth thickness overlying the inverted refractive index pair; wherein the first refractive index is greater than the second refractive index; the third refractive index is greater than the second refractive index; and the fourth refractive index is less than the third refractive index.

In certain embodiments of an ARC, the first thickness and the fourth thickness correspond to a ¼wavelength thickness at a wavelength from 500 nm to 630 nm; and the second thickness and the third thickness correspond to a ¼wavelength thickness at a wavelength from 325 nm to 425 nm.

In certain embodiments of an ARC, the first refractive index and the third refractive index are greater than 2; and the second refractive index and the fourth refractive index is less than 2.

In certain embodiments of an ARC, the first and third materials comprise TiO₂, the second and fifth materials comprise SiO₂, and the fourth material comprises Al₂O₃.

In certain embodiments of an ARC, the first refractive index and the third refractive index are greater than 2, the second refractive index and the fifth refractive index are from 1 to 2; and the fourth refractive index is less than the first refractive index and greater than the second refractive index.

In certain embodiments of an ARC, the first and third materials comprise TiO₂, the second and fourth materials comprise Al₂O₃, and the fifth material comprises SiO₂.

In certain embodiments of an ARC, the first material and the third material comprise SiO₂, and the second material comprises TiO₂.

Embodiments of the present disclosure include photovoltaic cell comprising the anti-reflection coating.

Embodiments of the present disclosure further include methods of forming a multijunction solar cell with an anti-reflection coating, comprising providing a multijunction solar cell comprising a top subcell; and depositing an antireflection coating comprising at least one inverted refractive index pair overlying the top subcell, to provide the multijunction solar cell having an antireflection coating.

In certain embodiments, a broadband ARC, which is deposited over the uppermost front surface field of the epitaxial region of a multi junction solar cell, has three layers. The bottom-most layer of the ARC comprises TiO₂ and or SiC, the middle layer comprises Ta₂O₅, and the upper-most layer comprises Al₂O₃. In certain embodiments, a chemical protective layer comprising SiO₂ is deposited over the upper-most layer of the three-layer ARC during wafer processing. In certain embodiments, the material thickness of the TiO₂ and/or SiC layer is from 30 nm to 50 nm and is characterized by a refractive index between 2.6 to 2.7. In certain embodiments, the material thickness of the Ta₂O₅ layer is from 30 nm to 50 nm and is characterized by a refractive index of 2.20. In certain embodiments, the material thickness of the Al₂O₃ layer is from 80 nm to 150 nm and is characterized by a refractive index of 1.65. In certain embodiments, the material thickness of the chemical protective SiO₂ layer is from 0.01 nm to 15 nm and is characterized by a refractive index of 1.45. In certain embodiments, the thickness is from 1 nm to 12 nm, from 2 nm to 10 nm, from 4 nm to 8 nm, and in certain embodiments, from 5 nm to 15 nm.

The described three-layer broadband ARC can withstand annealing temperatures for metallization of the front contact on the solar cell by depositing each ARC layer with the required index and thickness at a rate of deposition that maintains uniformity of each layer without bubbles or cracks.

The subcells in the multijunction solar cell with the above-described three-layer ARC design may include one or more lattice matched and/or metamorphic subcells, which include, for example, tunnel junctions, a front surface field (FSF), an emitter, a depletion region, base and/or a back surface field. Semiconductor materials used in these subcells may include, for example, indium gallium phosphide, indium phosphide, gallium arsenide, aluminum gallium arsenide, indium gallium arsenide, germanium and dilute nitride compounds such as GaInNAsSb, GInNAsBi, GaInNAsSbBi, GaNAsSb, GaNAsBi, GaNAsSbBi, or a combination of any of the foregoing. For ternary and quaternary compound semiconductors, a wide range of alloy ratios can be used.

Certain embodiments of a three junction multijunction solar cell with the above-described three-layer ARC design, grown on a GaAs substrate, comprise an InGaP top subcell with a band gap between 1.84 eV and 1.91 eV and a front surface field (FSF) comprising InAlP. InAlP acts as a passivation layer for the InGaP subcell and prevents efficiency-reducing absorption of the solar spectrum into the top InGaP subcell. The top subcell (subcell 1), is defined as the subcell closest to the cap below the metal contact and ARC, the middle subcell is defined as the subcell below the top subcell (subcell 2), which is above the bottom subcell (subcell 3). In certain embodiments of a three junction multijunction solar cell, the InGaP top subcell has a band gap of 1.88 eV. Certain embodiments of a three junction multijunction solar cell may comprise a GaAs middle subcell. In certain embodiments, the GaAs middle subcell has a band gap of 1.415 eV. Another embodiment of a three junction multijunction solar cell may comprise a GaInAsNSb bottom subcell with a band gap between 0.85 eV and 1 eV, and in certain embodiments, a band gap of 0.965 eV. All subcells in a three junction multijunction solar cell may be lattice matched.

Certain embodiments of a three junction multijunction solar cell, with the above-described three-layer ARC design, grown on Ge, comprise a InGaP or AlInGaP top subcell with a band gap between 1.84-2.1 eV and a FSF comprising InAlP. Certain embodiments of a three-junction multijunction solar cell may comprise a GaAs, AlGaAs, or GaInAs middle, or second, subcell, below the top subcell. In certain embodiments, the middle subcell has a band gap of between 1.4 eV and 1.5 eV. A three junction multijunction solar cell may comprise a bottom GaInAsNSb subcell with a band gap between 0.85 eV and 1 eV. All subcells are lattice matched.

Certain embodiments of a four junction multijunction solar cell, with the above-described three-layer ARC design, grown on Ge, comprise a InGaP or AlInGaP top subcell with a band gap between 1.84 eV and 2.12 eV and a FSF comprising InAlP. The subcell below the top subcell, or second subcell, may comprise AlGaAs, GaAs, or GaInAs with a band gap between 1.4 eV and 1.65 eV. The third subcell, which is below the second subcell, may comprise GaInAsNSb with a band gap between 1 eV and 1.26 eV. The fourth and bottom-most subcell may comprise GaInAsNSb with a band gap between 0.85 eV and 1 eV. All subcells are lattice matched.

Another embodiment of a four junction multijunction solar cell, with the above-described three-layer ARC design, grown on Ge, comprises a InGaP or AlInGaP top subcell with a band gap between 1.84 eV and 2.12 eV and a FSF comprising InAlP. The subcell below the top subcell, or second subcell, may comprise AlGaAs, GaAs, or GaInAs with a band gap between 1.4 eV and 1.65 eV. The third subcell, which is below the second subcell, may comprise GaInAsNSb with a band gap between 0.9 eV and 1.26 eV. The fourth and bottom-most subcell may comprise Ge with a band gap of 0.68 eV. All subcells are lattice matched.

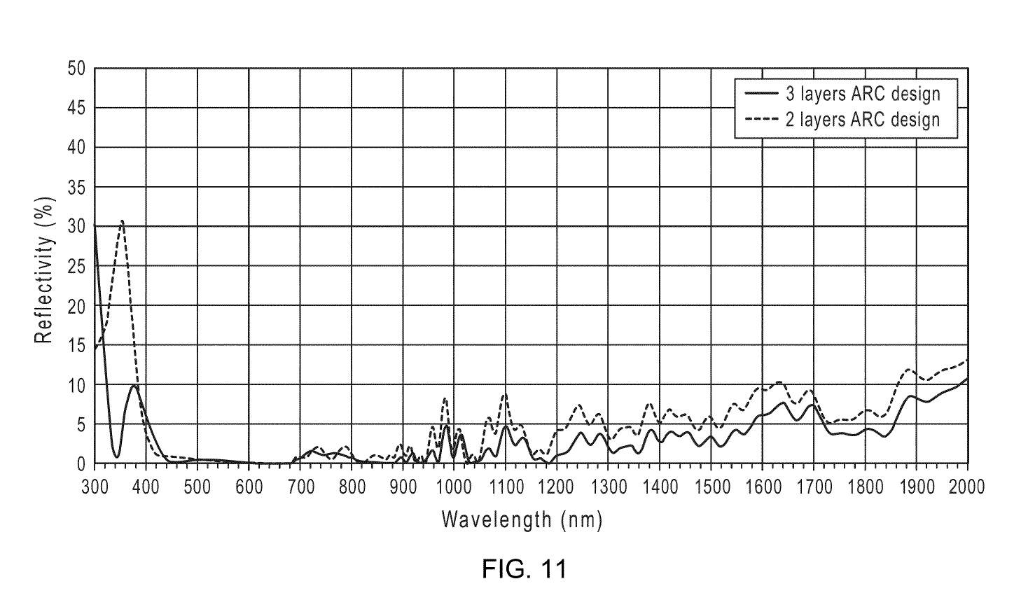

FIG. 11 shows a comparison of the simulated reflectivity losses between a two layer and a three layer ARC design for a three junction solar cell grown on GaAs. The calculated reflectivity losses for each subcell of a three junction solar with the two ARC designs is compared in Table 4.

TABLE 4
Reflectivity loses for two anti-reflectivity coating design forms by
two layer TiO₂/Al₂O₃ ARC and three layer TiO₂/Ta₂O₅/Al₂O₃
ARC on a three-junction multijunction solar cell comprised
of GaAs/GaInAsSb/InGaP.

| | Design | | | | | |
|---|---|---|---|---|---|---|
| | 2-Layer ARC | | | 3-Layer ARC | | |
| | Top | Middle | Bottom | Top | Middle | Bottom |
| | cell | cell | cell | cell | cell | cell |
| Reflectivity | 0.97 | 0.91 | 3.37 | 0.78 | 0.65 | 1.61 |
| loses (%) | | | | | | |

A three layer ARC design significantly reduces reflectivity losses from the top, middle and bottom subcells. A three-layer ARC design reduces reflectivity losses for the bottom subcell by more than half compared to the two-layer ARC design. The reflectivity losses are calculated using the output current of each subcell, the AM1.5D spectrum, and the reflectivity. The percent reflectivity is relative to an ideal ARC with no reflectivity.

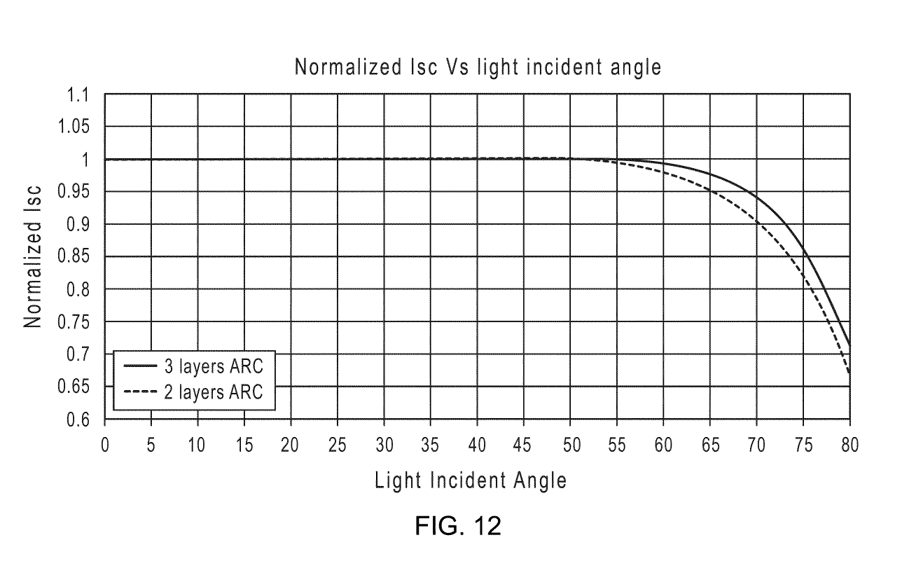

FIG. 12 shows the normalized short circuit current (Isc) versus incident light angle for solar cells having a three-layer ARC design for a two-layer ARC design. As indicated by the data, due to reduced reflectivity loses in the bottom subcell, the three-layer ARC design provides enhanced short circuit current, particularly at incident light angles greater than about 55°. This decreased reflectivity loss in the bottom subcell thereby increases the minimum current through the subcell, increasing overall cell efficiency.

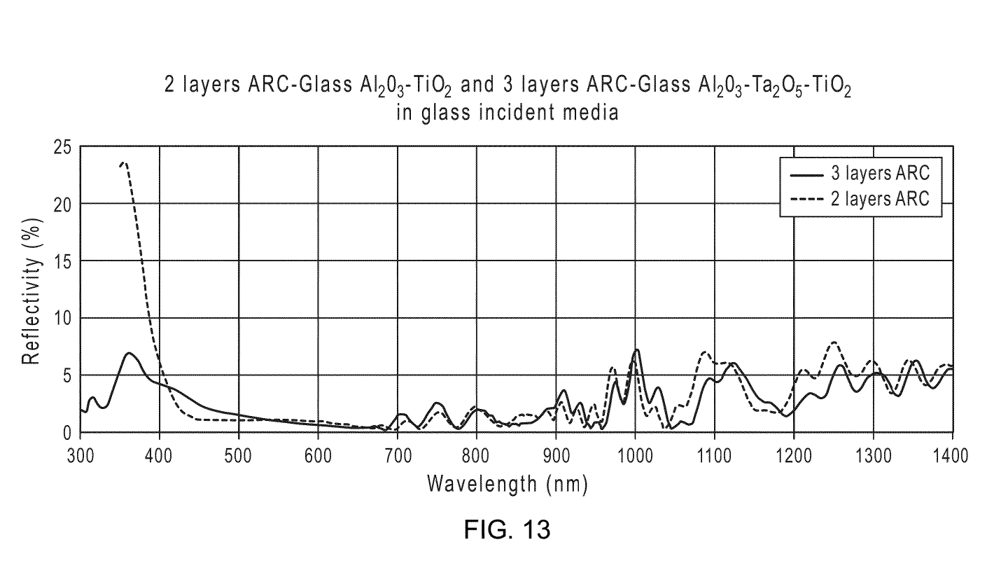

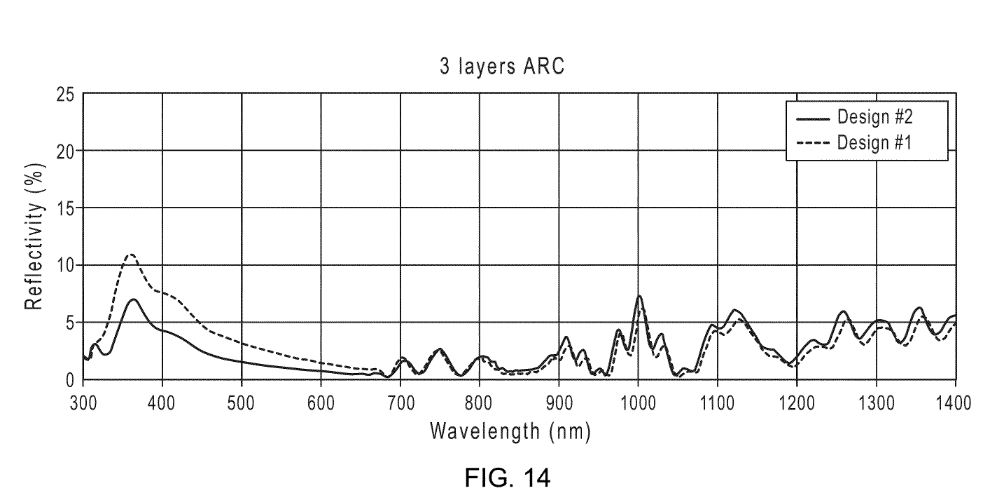

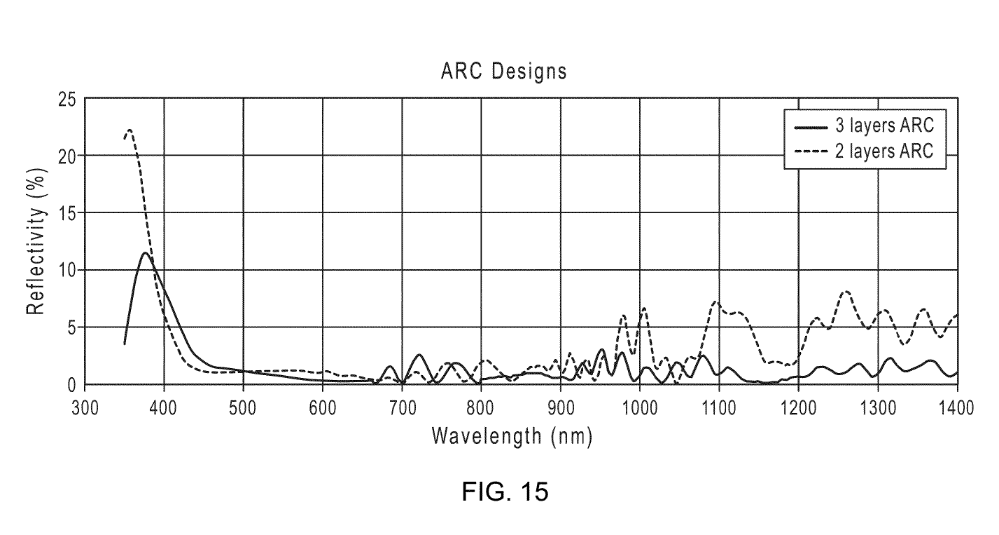

FIGS. 13, 14, and 15 show measured reflectivity as a function of wavelength for a three junction multijunction solar cell grown on GaAs having a three-layer ARC with a TiO₂ bottom layer, a Ta₂O₅ the middle layer, and a Al₂O₃ upper layer; compared to the measured reflectivity of a two-layer ARC. The reflectivity was obtained for an incident AM1.5D spectrum with a cover glass. As indicated by FIGS. 12, 13, and 14, a three-layer ARC provides decreased reflectivity across the low and high-end wavelengths of the solar spectrum. The decreased reflectivity results in improved solar cell efficiency.

In certain embodiments, a multijunction solar cell comprises an epitaxial region comprising a substrate, an uppermost front surface field region, and a plurality of subcells, wherein each of the plurality of subcells is lattice matched to the substrate; a plurality of cap regions overlying a first portion of the uppermost front surface field region; and an antireflection coating overlying a second portion of the uppermost front surface field region, wherein the antireflection coating comprises three or more dielectric films.

In certain embodiments of a multijunction solar cell the substrate comprises Ge or GaAs.

In certain embodiments of a multijunction solar cell the plurality of subcells comprises three or more subcells, wherein each of the three or more subcells comprises a material selected from GaInNAsSb, InGaAs, AlInGaAs, AlInGaP, InGaP, InP, and a combination of any of the foregoing.

In certain embodiments of a multijunction solar cell an antireflection coating comprises a first layer comprising a material selected from TiO₂, SiC, and a combination thereof; a second layer comprising Ta₂O₅; and a third layer comprising Al₂O₃.

In certain embodiments of an antireflection coating, the first layer has a thickness between 30 nm and 50 nm and is characterized by a refractive index between 2.6 and 2.7.

In certain embodiments of an antireflection coating, the second layer has a thickness between 30 nm and 50 nm and is characterized by a refractive index of 2.20.

In certain embodiments of an antireflection coating, the third layer has a thickness between 80 nm and 150 nm and is characterized by a refractive index of 1.65.

In certain embodiments, a multijunction solar cell comprises a chemical protective layer overlying the antireflection coating, wherein the chemical protection layer comprises SiO₂.

In certain embodiments, the chemical protective layer has a thickness between 1 nm and 15 nm and is characterized by a refractive index of 1.45.

In certain embodiments of a multijunction solar cell, the antireflection coating overlies the plurality of cap regions and the uppermost front surface field region.

In certain embodiments, a multijunction solar cell comprises an epitaxial region comprising a substrate, an uppermost front surface field region, and a plurality of subcells, wherein each of the plurality of subcells is lattice matched to the substrate; a plurality of cap regions overlying a first portion of the uppermost front surface field region; an antireflection coating overlying a second portion of the uppermost front surface field region, wherein the antireflection coating comprises three or more dielectric films; and a protective device, a concentrating optic, or a combination thereof, overlying the antireflection coating.

In certain embodiments, methods of forming a multijunction solar cell with an anti-reflection coating, comprise providing a multijunction solar cell comprising a top subcell; and depositing an antireflection coating comprising at least one inverted refractive index pair overlying the top subcell, to provide the multijunction solar cell having an antireflection coating.

Finally, it should be noted that there are alternative ways of implementing the embodiments disclosed herein. Accordingly, the present embodiments are to be considered as illustrative and not restrictive. Furthermore, the claims are not to be limited to the details given herein, and are entitled their full scope and equivalents thereof.

What is claimed is:

1. An anti-reflection coating comprising at least one inverted refractive index pair, wherein the at least one inverted refractive index pair comprises:
an upper layer comprising a first material characterized by a first refractive index and a first thickness; and
a lower layer comprising a second material characterized by a second refractive index and a second thickness,
wherein the upper layer overlies the lower layer, and the first refractive index is higher than the second refractive index.

2. The anti-reflection coating of claim 1, wherein a total thickness of the upper layer and the lower layer represents a ¼wavelength optical thickness at a wavelength from about 300 nm to 425 nm.

3. The anti-reflection coating of claim 1, wherein a total thickness of the upper layer and the lower layer is from about 20 nm to about 200 nm.

4. The anti-reflection coating of claim 1, comprising one or more layers comprising a material characterized by a refractive index lower than the first refractive index overlying the at least one inverted refractive index pair.

5. The anti-reflection coating of claim 1, comprising one or more layers comprising a material characterized by the first refractive index beneath the at least one inverted refractive index pair.

6. The anti-reflection coating of claim 1, wherein the anti-reflection coating is characterized by a transmission of about 100% and a reflectance less than about 5% from 400 nm to 1700 nm.

7. The anti-reflection coating of claim 1, wherein,
the first refractive index is greater than 2 at a wavelength of about 500 nm; and
a second refractive index is from 1 to 2 at a wavelength of approximately 500 nm.

8. The anti-reflection coating of claim 1, wherein,
the first refractive index is greater than 1.5 at a wavelength of about 500 nm; and
the second refractive index is from 1 to 1.5 at a wavelength of approximately 500 nm.

9. The anti-reflection coating of claim 1, wherein,
the at least one inverted index pair is characterized by a ¼wavelength thickness at a first wavelength; and
the anti-reflection coating comprises at least one layer overlying the inverted index pair comprising a material characterized by a refractive index lower than the first refractive index and a ¼wavelength thickness at a second wavelength, wherein the first wavelength and the second wavelength are different.

10. The anti-reflection coating of claim 9, wherein the second wavelength is longer than the first wavelength.

11. The anti-reflection coating of claim 9, wherein the first wavelength is from about 325 nm to about 425 nm and the second wavelength is from about 520 nm to about 630 nm.

12. The anti-reflection coating of claim 1, wherein,
the inverted index pair is characterized by a ¼wavelength thickness at a first wavelength; and
the at least one inverted index pair overlies at least one third layer, wherein the at least one third layer comprises a material characterized by a refractive index higher than the second refractive index and a ¼wavelength thickness at a second wavelength, wherein the first wavelength and the second wavelength are different.

13. The anti-reflection coating of claim 12, wherein the second wavelength is longer than the first wavelength.

14. The anti-reflection coating of claim 12, wherein the first wavelength is from about 325 nm to about 425 nm and the second wavelength is from about 520 nm to about 630 nm.

15. The anti-reflection coating of claim 1, comprising second refractive index pair and a third refractive index pair overlying the first refractive index pair.

16. The anti-reflection coating of claim 1, comprising at least one third layer comprising a third material characterized by a refractive index higher than the second refractive index and a ¼wavelength thickness at a third wavelength.

17. The anti-reflection coating of claim 1, wherein the anti-reflection coating is characterized by a reflectance at wavelengths from 450 nm to 1700 nm at an incident angle of 0 degrees (normal) is less than 5%.

18. An anti-reflection coating comprising:
a first layer comprising a first material characterized by a first refractive index and by a first thickness;
an inverted refractive index pair overlying the first layer, wherein the inverted refractive index pair comprises:
a second layer comprising a material characterized by a second refractive index and by a second thickness; and
a third layer comprising a material characterized by a third refractive index and by a third thickness; and
a fourth layer comprising a material characterized by a fourth refractive index and a fourth thickness overlying the inverted refractive index pair; wherein
the first refractive index is greater than the second refractive index;
the third refractive index is greater than the second refractive index; and
the fourth refractive index is less than the third refractive index.

19. A photovoltaic cell comprising the anti-reflection coating of claim 1.

20. A multijunction solar cell comprising:
an epitaxial region comprising a substrate, an uppermost front surface field region, and a plurality of subcells, wherein each of the plurality of subcells is lattice matched to the substrate;
a plurality of cap regions overlying a first portion of the uppermost front surface field region; and
an antireflection coating overlying a second portion of the uppermost front surface field region, wherein the antireflection coating comprises three or more dielectric films.

21. The multijunction solar cell of claim 20, wherein the antireflection coating comprises:
a first layer comprising a material selected from TiO₂, SiC, and a combination thereof;
a second layer comprising Ta₂O₅; and
a third layer comprising Al₂O₃.

22. The multijunction solar cell of claim 21, wherein,
the first layer has a thickness between 30 nm and 50 nm and is characterized by a refractive index between 2.6 and 2.7;
the second layer has a thickness between 30 nm and 50 nm and is characterized by a refractive index of 2.20; and
the third layer has a thickness between 80 nm and 150 nm and is characterized by a refractive index of 1.65.
